(19) United States
(12) Patent Application Publication
(10) Pub. No.: US 2001/0016048 A1
(43) Pub. Date: Aug. 23, 2001

(54) AUDIO REPRODUCTION ARRANGEMENT AND TELEPHONE TERMINAL

(75) Inventor: JUHA RAPELI, CHANGE (FR)

Correspondence Address: DICRAN HALAJIAN, U S PHILIPS CORPORATION, 580 WHITE PLAINS ROAD, TARRYTOWN, NY, 10591

(73) Assignee: PHILIPS CORPORATION

(21) Appl. No.: 09/179,167

(22) Filed: Oct. 26, 1998

(30) Foreign Application Priority Data
Oct. 28, 1997 (EP) 97402557.9

(51) Int. Cl. H03G 3/00

(52) U.S. Cl. 381/106; 381/104

(57) ABSTRACT

In a audio reproduction arrangement (2) such as a mobile phone terminal the decoded speech signal is compressed by compression means (14) in order to improve the understanding of the speech signal in the presence of strong background noise.

In a prior art audio reproduction arrangement the compression ratio is determined in response to a background noise level which is determined by a suitable detection device. In such a detection the capability of the user to deal with the background noise is not taken into account.

According to the inventive concept of the present invention, the audio reproduction device (2) comprises control means (8) for setting the compression ratio to a value being dependent on a volume setting entered by a user by means of a user interface (6).

The present invention is related to an audio reproduction arrangement comprising an amplifier for amplifying an audio signal and compressing means for compressing the dynamic range of the audio signal.

The present invention is also related to a telephone terminal and an audio reproduction method.

An audio reproduction arrangement according to the preamble is known from the laid open German patent application DE 195 33 260 A1. Such audio reproduction arrangements can e.g. be used in fixed or mobile telephone terminals.

A property of audio signals such as speech signals is that it comprises parts with low signal levels and parts with high signal levels. At low background noise levels, the reproduction of these audio signals can be done in a way that all parts of the audio signal can be understood by a listener. At higher background noise levels the reproduction of these audio signals becomes more difficult and some of the parts with a low signal level cannot be understood anymore.

In the audio reproduction arrangement according to the above mentioned German patent application the audio signal is compressed to reduce the dynamic range of the audio signal i.e. the ratio between the level of the high level parts of the audio signal and the parts low level parts of the audio signal. This compression is performed in dependence on the background noise level which is measured with a suitable device.

In the audio reproduction arrangement according to the above mentioned patent application the reduction of the compression ratio is determined by a fixed rule. This fixed rule does not take the ability of the user to deal with the back ground level into account, which may lead to a decrease of the reproduction of the audio signal.

An object of the present invention is to provide an audio reproduction arrangement according to the above mentioned German patent application in which the compression of the audio signal takes the ability of the user to deal with the background noise into account.

To achieve said objective, the audio reproduction arrangement according to the invention is characterized in that the audio reproduction arrangement comprises control means for adjusting the amount of compression in dependence on a volume setting.

The present invention is based on the recognition that the volume setting is a useful measure for the listening conditions. If the background noise level is high, the user will choose a higher volume setting in order to be able to understand the speech signal from the audio reproduction arrangement. This recognition can e.g. be used by performing compression to improve the understanding under high level background noise if the volume setting exceeds a predetermined value.

An embodiment of the invention is characterized in that the compressing means are arranged for limiting the level of high level parts of the audio signal if the volume setting is above a predetermined value.

By limiting the level of the high level parts of the audio signal if the volume setting exceeds a predetermined value, it is obtained that the low level parts of the audio signal can be emphasized without that the total audio level exceeds a given maximum value. This maximum represents the maximum audio level which is regarded as acceptable for a user.

A further embodiment of the invention is characterized in that the compressing means are arranged for enhancing the level of low level parts of the audio signal if the volume setting is below a further predetermined value.

Below a certain volume setting it is almost certain that the level of the low level parts of the audio signal is below the level of the background noise or hearing threshold. In such a case enhancing the level of the low level parts of the audio signal can improve the understanding of the speech signal.

A still further embodiment of the invention is characterized in that the compressing means are arranged for increasing the amount of compression with increasing volume setting above said predetermined value.

When the amount of compression increased (smaller compression ratio) with increasing volume setting, it is possible to increase the volume of the low level parts of the speech signal without having to exceed the maximum level of the audio signal.

A still further embodiment of the invention is characterized in that the compressing means are arranged for increasing the amount of compression with decreasing volume setting below said further predetermined value.

When the amount of compression is increased with decreasing volume setting, it is possible to maintain the volume of the low level parts of the speech signal at the same level and to decrease the level of the higher level parts of the speech signal.

The invention will now be explained with reference to the drawing figures. Herein shows:

FIG. 1, a block diagram of a telephone terminal using the present invention;

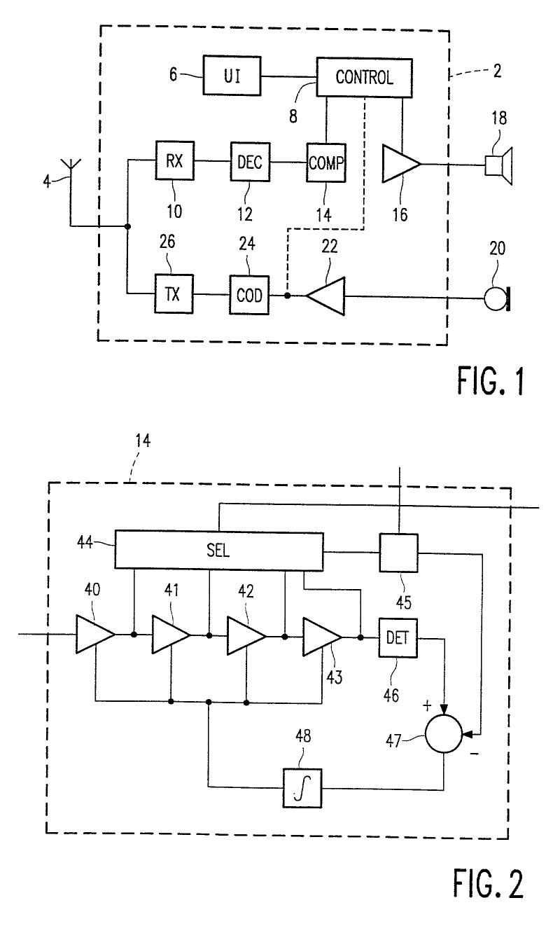

FIG. 2, a block diagram of the compression means to be used in the telephone terminal according to FIG. 1;

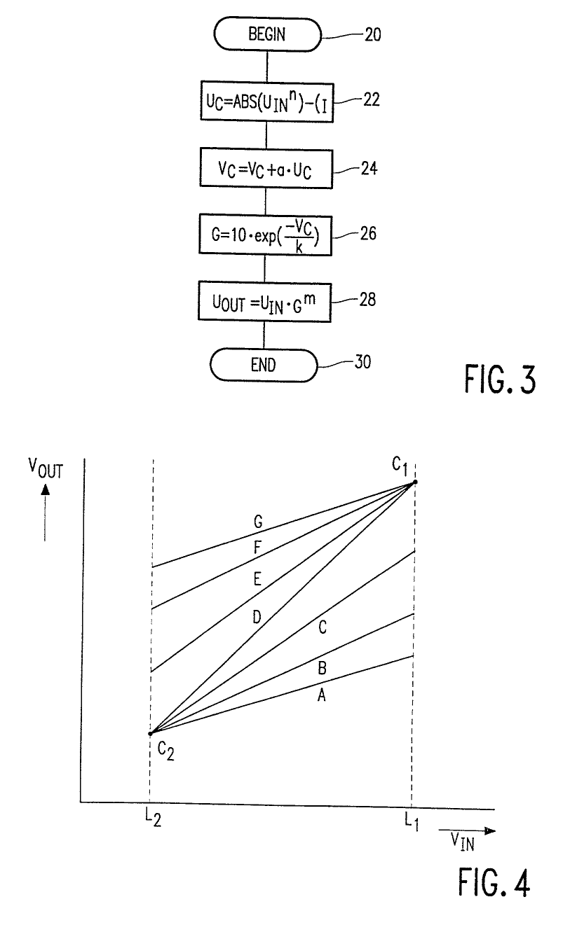

FIG. 3, a flow diagram of a program for a programmable processor for implementing the compression means;

FIG. 4, a graph showing a first example of the output level of the reproduction arrangement as function of the input level with the volume setting as parameter;

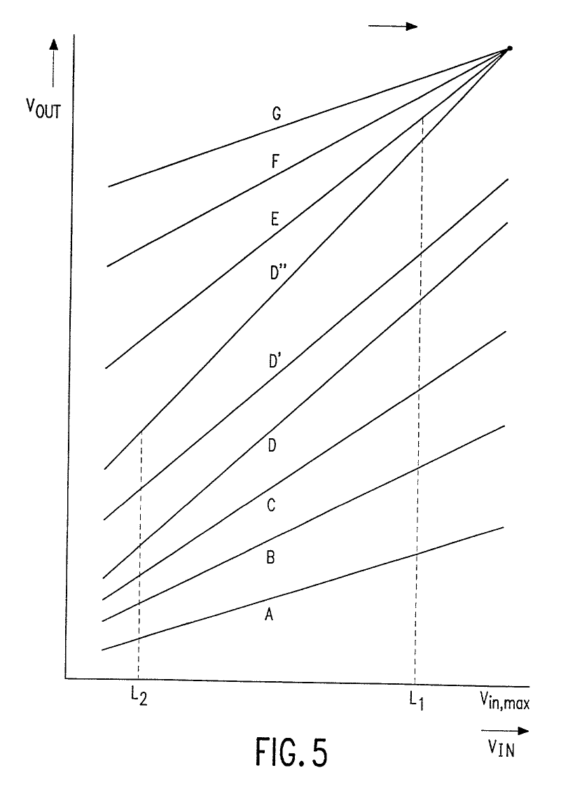

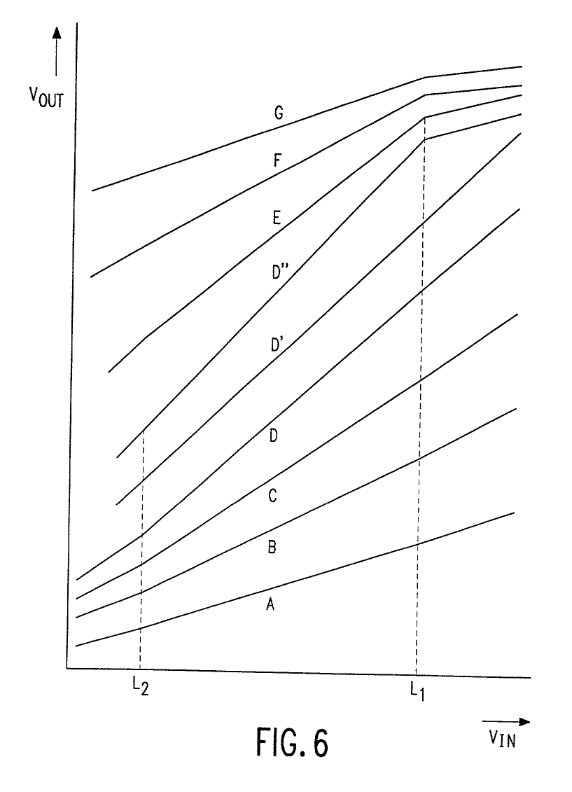

FIG. 5, a graph showing a second example of the output level of the reproduction arrangement as function of the input level with the volume setting as parameter;

FIG. 6, a graph showing a third example of the output level of the reproduction arrangement as function of the input level with the volume setting as parameter.

In the (mobile) telephone terminal according to FIG. 1, an antenna 4 is connected to an input of a receiver 10. The receiver 10 is arranged for receiving, demodulating and detection of the signal received from the antenna 4. The output of the receiver 10 is connected to an input of a speech decoder 12. The speech decoder 12 derived a decoded speech signal from the output signal of the receiver 10.

The output of the speech decoder 12 is connected to an input of the compression means 14 according to the inventive concept of the present invention. The output of the compression means 14 is connected to the input of an amplifier 16. The output of the amplifier 16 is connected to a loudspeaker 18.

A user interface 6, normally comprising a plurality of buttons and an LCD display is connected to a control device 8. A first output signal of the control device 8 is connected to a control input of the compression means. This allows the transmission of control signals from the control device 8 to the compression means 14 in response to instructions entered by the user on the user interface 6. In this way it becomes possible to control the amount of compression of the compression means 14 in response to the volume setting entered by the user by means of the user interface 6. The audio setting can be entered by the user in a well known way e.g. by activating up/down keys on the user interface 6.

A second output of the control device 8 is connected to a control input of the amplifier 16 in order to control the volume of the reproduced audio signal.

An output of a microphone 20 is connected to an amplifier 22 for amplifying the microphone signal to a level suitable for encoding by a speech encoder 24. The output of the amplifier 22 is connected to an input of the speech encoder 24 which derives an encoded speech signal from the output signal of the amplifier 22. Optionally, the output of the amplifier 22 is connected to an input of the control device 8 to enable to adapt the setting of the compression means 14 to the background noise level.

The output of the speech encoder 24 is connected to an input of the transmitter 26. The transmitter 26 is arranged for modulating the output signal of the speech encoder 24 on a carrier for transmission by the antenna 4.

In the compression means according to FIG. 2, the input signal is applied to a cascade connection of four equal controllable amplifiers 40, 41, 42 and 43. The outputs of each of the amplifiers 40, 41, 42 and 43 are connected to a corresponding input of a selector 44. The output of the amplifier 43 is also connected to an input of a level detector 46 which is arranged for detecting the level of the output signal of amplifier 43.

The output of the level detector 46 is connected to a first input of a subtractor 47. The second input of the subtractor 45 receives its input signal from a control device 45. The output of the subtractor 47 is connected to an input of an integrator 48, and the output of the integrator 48 is connected to a control input of the amplifiers 40, 41, 42 and 43.

The control loop comprising the amplifiers 40, 41, 42, 43 and 44, the level detector 46 the subtractor 47 and the integrator 48 causes the output level UOUT of the amplifier 43 to be equal to the reference level C_{I} at the input of the subtractor 47. For a cascade connection of n amplifiers having reached a steady operation condition, the following relationship between the output level U_{OUT} of the amplifier 43 and the input level V_{IN} of the amplifier 40 can be written:

U_{OUT}=C_{I}=U° IN·Gⁿ (A)

In (1) G is the gain of each of the amplifiers 40 . . . 43. If the output signal of the compression means 14 is taken from the output of the m^{th} amplifier (amplifier 43 is 0^{th} amplifier, amplifier 42 is 1^{st} amplifier, amplifier 41 is 2^{nd} amplifier etc.), for the output signal of the compression means U_{OUTC} can be written:

$${U}_{OUTC} = {( \frac{{C}_{I}}{{U}_{IN}} )}^{\frac{m}{n}} \cdot {U}_{IN} \qquad ( B )$$

An input signal V_{IN} changing from U_{IN1} to U_{IN2} causes the output of the compression means 14 to change from U_{OUTC1} to U_{OUTC2}. For the ratio U_{OUTC1}/U_{OUTC2} as function of the ratio U_{IN1}/U_{IN2} can be derived from (2):

$$\frac{{U}_{OUTC1}}{{U}_{OUTC2}} = \frac{{( \frac{{C}_{I}}{{U}_{IN1}} )}^{\frac{m}{n}} \cdot {U}_{IN1}}{{( \frac{{C}_{I}}{{U}_{IN2}} )}^{\frac{m}{n}} \cdot {U}_{IN2}} = {( \frac{{U}_{IN1}}{{U}_{IN2}} )}^{1 - \frac{m}{n}} \qquad ( C )$$

From (3) it is clear that the changes in the output signal are reduced by an amount defined by a factor 1−m/n. This factor is called the compression ratio. n

In the compression means 14 the compression ratio is chosen by a selection of the output of one of the amplifiers 40, 41, 42 or 43 by the selection means 44 which are controlled by the control means 45, which receives its information from the control device 8 in FIG. 1. The control means 45 further provide the a reference value C_{I}.

An example of the achievable compression ratios by switching the outputs of the amplifiers is given in the table below:

| Number of amplifiers (n) | Position of output (m) | Compression ratio |
|---|---|---|
| any | 0 | 1 |
| 4 | 1 | 0.75 |
| 3 | 1 | 0.66 |
| 2 | 1 | 0.50 |
| 3 | 2 | 0.33 |
| 4 | 3 | 0.25 |

The integrator 48 is present to determine the speed of the control loop. For telephone voice signals with a bandwidth from 300 Hz to 3400 Hz an integration time constant of 20 milli seconds has been found as a good value.

In the flow graph according to FIG. 3, the instructions have the meaning according to the following table:

| Number | inscription | meaning |
|---|---|---|
| 20 | BEGIN | The program is started. |
| 22 | U_{C} = ABS(U_{IN}ⁿ) − C_{I} | The difference between the absolute |
| | | value of the output signal and the |
| | | reference value is calculated. |
| 24 | V_{C} = V_{C} + a · U_{C} | The new value of the control signal for |
| | | the gain stages is calculated |
| 26 | $G = 10 \cdot exp ( \frac{- {V}_{C}}{k} )$ | The actual gain of the gain stages is calculated. |
| 28 | U_{OUT} = U_{IN} · G^{m} | The output signal of the compression |
| | | means are calculated. |
| 30 | END | The program is terminated. |

In the flow graph according to FIG. 3, the same variables are used as for the explanation of the circuit according to FIG. 2. The program according to FIG. 3 has to be executed with a predetermined repetition period.

In instruction 20, the program is started. In instruction 22 a difference between the absolute value of U_{IN}ⁿ is calculated and the difference between said absolute value and the reference value C_{I} is determined. The actions performed by this instruction 20 correspond to the operation of the level detector 46 and the subtractor 47 in the compression means according to FIG. 2.

In instruction 24 the new value of the control signal V_{C} is calculated from the previous value of V_{C} and the difference calculated in instruction 20. The constant a determines the time constant of the compression means. The time constant is further dependent on the constant k and the repetition period.

In instruction 26 the actual gain value of each gain stage is calculated from the control signal V_{C}. The relation between the control signal V_{C} and the actual gain G is exponential in order to be able to achieve a large gain variation with a modest change in the control signal V_{C}.

In instruction 28 the compressed output signal of the compression means is calculated from the input signal of the compression means. As explained above, the compression ratio obtained depends on the value of m. Because the present implementation does not use actual amplifiers it is possible to have non-integer values of m, allowing arbitrary compression ratios to be chosen.

In instruction 30 the program is terminated, but the values of its internal variables are maintained for the next call of the program 30. It is possible to impose certain minimum and/or maximum values to G. With respect to the exponential relationship between G and V_{C} it is observed that this exponential relationship can be stored in a lookup table in order to reduce the computational complexity of determining the value of G from V_{C}.

In FIG. 4 graphs are shown of the output audio level of the terminal as function of the input level from the speech decoder 12, with the volume setting as parameter. The different values of the volume setting are indicated with A, B, C, D, E, F and G. It is further observed that the gain of the amplifier 16 is set to a constant value.

Graph D is applicable for a medium volume setting. In that case no compression is involved, but the value of C_{I} is made proportional to the level of the input signal of the compression means 14.

Graphs E, F and G are applicable for an increasing volume setting. In Graph E a compression ratio of 0.75 is used, and the reference level C_{I} is set to a value L₁. In Graph F a compression ratio of 0.5 is used, and in graph G a compression ration of 0.33 is used. In both cases (F and G) the value of C_{I} remains equal to L₁.

Graphs C, B and A are applicable for an decreasing volume setting. In Graph C a compression ratio of 0.75 is used, and the reference level C_{I} is now set to a value L₂. In Graph B a compression ratio of 0.5 is used, and in graph A a compression ration of 0.33 is used. In both cases (B and A) the value of C_{I} remains equal to L₂.

It is observed that in the cases E, F and G the compression means are operated in an area where the input signal is smaller than the output signal of the compression means, and that in the cases C, B and A the compression means are operated in an area where the input signal is larger than the output signal of the compression means.

FIG. 5 shown the level of the output signal of the amplifier 16 as function of the input level of the compression means 14. In the situation displayed in this graph the amplification of the amplifier 16 is not constant as in the graphs according to FIG. 4, but the gain of the amplifier 16 is increased with the volume setting. In the graphs D, D′ and D″ no compression takes place. The value of C_{I} is made equal to the value of the input level of the compression means 14.

In the graphs E, F and G the same compression ratios as in the graphs E, F and G of FIG. 4 are used, but the present graphs E, F and G differ in the gain setting of the amplifier 16. The value of C_{I} is equal to L₁. In the graphs A, B and C the same compression ratios as in the graphs A, B and C of FIG. 4 is used, but the present graphs A, B and C differ in the gain setting of the amplifier 16. The value of C_{I} for the volume settings A, B and C is equal to L₂.

FIG. 6 shows the output level of the amplifier 16 as function of the input level of the compression means 14, if level dependent compression is used. For the volume settings D”, E, F and G, the amount of compression is increased if the input signal of the compression means exceeds the value L₁. For volume setting G the amount of compression is increased from a compression ratio of 0.33 to a compression ratio of 0.25, for volume setting F the amount of compression is increased from a compression ratio of 0.5 to a compression ratio of 0.33, for the volume setting E the amount of compression is increased from a compression ratio of 0.75 to a compression ratio of 0.5, and for volume setting D″ the amount of compression is increased from a compression ratio of 1 (no compression) to a compression ratio of 0.75.

For the volume setting D′ the relation between input signal and output signal is the same as in FIG. 6.

For the volume settings A, B, C and D, the amount of compression is increased if the input level of the compression means falls below the value L₂. For volume setting A the amount of compression is increased from a compression ration of 0.33 to a compression ratio of 0.25, for volume setting B the amount of compression is increased from a compression ratio of 0.5 to a compression ration of 0.33, for the volume setting C the amount of compression is increased from a compression ratio of 0.75 to a compression ratio of 0.5, and for volume setting D the amount of compression is increased from a compressio ratio of 1 (no compression) to a compression rate of 0.75.

1. Audio reproduction arrangement comprising an amplifier for amplifying an audio signal and compressing means for compressing the dynamic range of the audio signal, characterized in that the audio reproduction arrangement comprises control means for adjusting the amount of compression in dependence on a volume setting.

2. Audio reproduction arrangement according to claim 1, characterized in that the compressing means are arranged for limiting the level of high level parts of the audio signal if the volume setting is above a predetermined value.

3. Audio reproduction arrangement according to claim 1 or 2, characterized in that the compressing means are arranged for enhancing the level of low level parts of the audio signal if the volume setting is below a further predetermined value.

4. Audio reproduction arrangement according to claim 2 or 3, characterized in that the compressing means are arranged for increasing the amount of compression with increasing volume setting above said predetermined value.

5. Audio reproduction arrangement according to claim 2, 3 or 4, characterized in that the compressing means are arranged for increasing the amount of compression with decreasing volume setting below said further predetermined value.

6. Audio reproduction arrangement according to one of the previous claims, characterized in that the arrangement comprises background noise level detection means, and in that the compression means are arranged for adjusting the amount of compression also in dependence on a background noise level.

7. Telephone terminal comprising an audio reproduction arrangement according to one of the claims 1, 2, 3, 4, 5 or 6.

8. Telephone terminal according to claim 7, characterized in that the telephone terminal comprises control means for switching off the compression after the termination of a call.

9. Audio reproduction method amplifying an audio signal and compressing the dynamic range of the audio signal, characterized in that the audio reproduction method comprises adjusting the compression ratio in dependence on a volume setting.

10. Audio reproduction method according to claim 8, characterized in that the method comprises limiting the level of high level parts of the audio signal if the volume setting is above a predetermined value.

11. Audio reproduction method according to claim 9 or 10, characterized in that the method comprises enhancing the level of low level parts of the audio signal if the volume setting is below a further predetermined value.
